(19) United States
(12) Patent Application Publication
(10) Pub. No.: US 2007/0247822 A1
(43) Pub. Date: Oct. 25, 2007

(54) METHOD FOR THE PRODUCTION OF A PRINTED CIRCUIT STRUCTURE AS WELL AS A PRINTED CIRCUIT STRUCTURE THUS PRODUCED

(75) Inventor: Gerhard Naundorf, Lemgo (DE)

Correspondence Address: DARBY & DARBY P.C., P.O. BOX 770, Church Street Station, New York, NY, 10008-0770, US

(73) Assignee: LPKF LASER & ELECTRONICS AG, Garbsen (DE)

(21) Appl. No.: 11/734,387

(22) Filed: Apr. 12, 2007

(30) Foreign Application Priority Data
Apr. 12, 2006 (DE) 102006017630.8-34

(51) Int. Cl. H05K 7/00; H05K 3/00

(52) U.S. Cl. 361/748; 29/829

(57) ABSTRACT

A method for the production of a carrier material in current-free metallization baths includes first exposing the plate-shaped carrier material to selective electromagnetic radiation of an Nd:YAG laser in order to create printed circuit structures on the carrier material as highly reactive aluminum particles by breaking-up non-conductive aluminum nitride that is extremely finely dispersed in the carrier material. At the same time, nitrogen is released, which prevents an undesired oxidation of the aluminum particles. Subsequently, at least one copper layer is applied current-free onto the printed circuit structure. In addition, a printed circuit structure produced on the carrier material by means of this method.

Priority is claimed to German Patent Application No. DE 10 2006 017630.8, filed on Apr. 12, 2006, the entire disclosure of which is incorporated by reference herein.

The present invention relates to a method for metallizing a printed circuit structure on a carrier material in a current-free metallization bath and it also relates to a printed circuit structure produced on a carrier material by means of this method.

### BACKGROUND

Such methods are employed in actual practice, for example, in the production of circuit carriers made of thermoplastics employing an injection molding process, the so-called MID technology, the abbreviation MID standing for moulded interconnect device. The objective of MID technology is to combine electrical and mechanical functions in a single component. In this process, the printed circuits are integrated into the housing, thus replacing the conventional printed circuit board. Both the weight and installation space can be effectively reduced. In comparison to alternative production methods, the methods employing MID technology have the advantage that the tool costs can be kept relatively low. Moreover, the number of necessary process steps can be reduced, allowing very cost-effective manufacture, even in the case of medium-sized production runs.

Methods for the above-mentioned purpose are already known from German patent applications DE 197 23 734 A1 and DE 197 31 346 A1, both of which are incorporated by reference herein, in which non-conductive metal chelate complexes are incorporated into a non-conductive carrier material in order to produce printed circuit structures that are fine and firmly bonded, after which metallizing grains are split off from the metal chelate complexes in a structured manner by means of laser radiation, whereby these grains initiate a subsequent chemically reductive metallization in the irradiated portions of the surface.

A method of this generic type as well as a printed circuit structure produced according to this method are disclosed, for instance, in WO 03/005784 A2, which is incorporated by reference herein. In order to be able to provide printed circuit structures which can be easily and reliably produced on circuit carriers, which contain a relatively low proportion of nucleating additives and which are stable even at soldering temperatures and also in order to create a simple and reliable method for the production of printed circuit structures, insoluble, non-conductive, spinel-based higher oxides that are highly stable under heat and resistant in aqueous, acidic or alkaline metallization baths are admixed into the carrier material, after which the carrier material is processed into components or else applied as a coating onto components and, in the area where the printed circuit structures are to be created, heavy-metal grains are released by means of electromagnetic radiation, after which these areas are metallized by chemical reduction.

International patent application WO 00/35259 A2, incorporated by reference herein, describes a method for the production of fine metallic printed circuit structures on an electrically non-conductive carrier material in which an electrically non-conductive heavy-metal complex made up of organic complexing agents is applied onto or incorporated into the carrier material, then the carrier material is selectively exposed to UV radiation in the area where the printed circuit structures are to be created, a process in which heavy-metal grains are released, and this area is metallized by chemical reduction. In this manner, the printed circuits can undergo fine structuring by means of a simplified and reliable method.

Furthermore, German patent applications DE 37 08 235 A1 and DE 39 42 472 A1, incorporated by reference herein, relate to the processing of aluminum-nitride ceramics by means of electromagnetic radiation.

### SUMMARY OF THE INVENTION

An object of the present invention is to provide a way to obtain a further improved method for metallizing a printed circuit structure on a carrier material in a current-free metallization bath. An alternate or further object of the present invention is to create a printed circuit structure produced according to this method.

The present invention provides a method for the production of a printed circuit structure on a carrier material, wherein the printed circuit structure is created on a high-molecular surface of the carrier material as electrically conductive surface phases with highly reactive aluminum particles by breaking up non-conductive aluminum nitride contained in extremely finely dispersed form in the carrier material, said aluminum particles being released in a high concentration with the concurrent formation of nitrogen and with the ablation of the high-molecular material, for instance, a polymer, whereby the areas surrounding the printed circuit structure remain unchanged. This translates into an accelerated method for the firmly bonded metallization of a surface structure in current-free baths, said method being implemented on the surface of high-molecular materials that have been physically modified by aluminum grains. In this process, the metal grains are released from the aluminum nitride by means of electromagnetic radiation. The invention constitutes a considerable improvement over the state of the art in that the electrically non-conductive aluminum-nitride particles contained in the material split off nitrogen when the aluminum grains are released, as a result of which the grains are protected against oxidation in the nitrogen atmosphere. The specific properties of the incorporated aluminum-nitride powder have a positive effect on the properties of the carrier material, leading to improved thermal conductivity, lower thermal expansion, improved bonding to the printed circuit structure and greater suitability for high electrical frequencies.

This process proves to be particularly promising when the metallization of the printed circuit structure of the carrier material is carried out in a current-free metallization bath and consequently the grains that are formed with a high number of grains per unit of area on the surface of the material and that are protected against oxidation in the nitrogen atmosphere make a considerable contribution to the accelerated metal deposition in current-free baths. Due to the released aluminum particles and their high number of grains per unit of area, the growth rates of the conventional chemical-reductive methods are already increased from about 0.1 μm/10 min to 1 μm/10 min immediately at the beginning of the metallization process, thus markedly improving the cost-effectiveness of this time-consuming production step. The combination of the high-molecular material, especially of a polymer, with aluminum nitride, also avoids outgassing of electrolyte inclusions of the chemical-reductive bath during subsequent soldering processes on the printed circuits since, due to the low proportion of aluminum-nitride powder amounting primarily to about 1% to 10% and due to the sheathing of the aluminum-nitride particles by the material matrix, especially the plastic matrix, electrolyte inclusions are avoided. Along with the formation of nitrogen, owing to the slight ablation of polymer particles and aluminum grains, the combination with the high-molecular materials also causes the printed circuits to form a printed circuit structure surface that is microporous in the structure area and that brings about a firm anchoring of the current-free metal structure and thus a high bonding strength of the metallized printed circuits. Since the aluminum-nitride particles are present in finely dispersed form throughout the carrier material, activation through electromagnetic radiation in through holes is likewise possible. In this context, the fast and reliable chemical-reductive metal deposition in the through holes is particularly advantageous. The addition of 1.0% to 5.0% yttrium oxide to the aluminum nitride exerts a positive effect on the bonding strength of the metallization.

The highly reactive aluminum particles of the printed circuit structures of the carrier material allow an unproblematic layer formation by the metallization in almost any desired manner. However, a particularly practical refinement of the method is one in which at least chromium, copper, nickel or gold are applied during the metallization in the current-free metallization bath, whereby especially a layer formation having individual layers of all of the above-mentioned constituents has proven to be very practical. Moreover, this also accounts for considerably faster metallization.

The energy input needed to break up the aluminum nitride contained in extremely finely dispersed form in the carrier material can be obtained in various ways. However, in a particularly promising modification, the electromagnetic radiation of a laser, especially within the wavelength spectrum from 0.125 μm to 11.0 μm, is employed in order to allow a selective breaking-up of the aluminum nitride by the laser beam. Naturally, the printed circuit structures can be created by writing with the laser beam or else in a single step by means of a stencil that limits the energy input. In comparison to other laser-induced methods, the aluminum-nitride compound incorporated as the active substance has the advantage that the breakdown of the compound with electromagnetic radiation is also possible employing a low energy density, thus saving on energy and leading to a longer service life of the laser sources used.

In actual practice, it has been found to be particularly useful when, in the area of the printed circuits that are to be created, highly reactive aluminum particles are simultaneously released by means of electromagnetic radiation, along with nitrogen formation and polymer removal, and these aluminum particles are then metallized by chemical reduction, in this manner creating a process that can be reliably controlled and that can be carried out within a short time span. The simultaneous ablation gives rise to undercuts on which the aluminum grains lie on the surface and which are filled up by the metallization.

It is likewise particularly promising when the insoluble aluminum-nitride powder that is highly stable under heat and resistant in aqueous, acidic or alkaline metallization baths is incorporated into the high-molecular surfaces of the carrier material using generally known techniques, after which the carrier material is processed into components or else applied as a coating onto components. This yields an especially versatile application possibility for the activatable carrier material thus created. To this end, the carrier material can be employed in a form that is liquid or solid, especially in a shapeable state, at room temperature.

Moreover, it is likewise particularly advantageous if, in an embodiment of the method according to the invention, the breaking-up of the aluminum nitride contained in the carrier material causes the aluminum particles to be formed with a concurrent ablation of the high-molecular material, especially of the polymer, along with the splitting off of nitrogen, creating a structure surface that promotes bonding. In a simple manner, this promotes the layer formation by the nitrogen that encloses the working zone and that serves to prevent undesired oxidation in that the structure surface improves the adhesion. At the same time, this accelerates the process.

Fundamentally, the carrier material can be selected as desired on the basis of the individual application purpose. In actual practice, however, one embodiment in which the non-conductive carrier material has a plastic or a polymer ceramic has proven to be particularly advantageous. Owing to its high-temperature resistance, the latter material permits, for instance, use in the vicinity of internal combustion engines and heating systems or else as an integral part of a component.

The second envisaged objective, namely, to create a printed circuit structure produced on a carrier material by means of this method, is achieved according to the invention in that the printed circuit structures are produced on high-molecular surfaces of the carrier material as highly reactive aluminum particles by breaking up non-conductive aluminum nitride contained in extremely finely dispersed form in the carrier material, a process in which the areas surrounding the printed circuit structure remain unchanged. Thanks to the high-molecular material containing the aluminum nitride as the carrier material, the printed circuits can be created with slight ablation of polymer particles along with the formation of nitrogen, whereby a microporous structure surface is formed in the structure area by the aluminum grains and this surface brings about a firm anchoring of the current-free metal structure and thus a high bonding strength of the metallized printed circuits.

In this context, it has also been found to be particularly advantageous in actual practice if the non-conductive carrier material, in addition to aluminum particles, also contains higher oxides having the structure of spinels or organic, thermally stable metal chelate complexes, so that the aluminum particles—as an admixture to other particles that likewise serve as the basis for creating the printed circuit structures, for instance, metal grains—allow an optimal adaptation to different requirements, thanks to the use of electromagnetic radiation to break up non-conductive metal compounds that are extremely finely dispersed in the carrier material.

### BRIEF DESCRIPTION OF THE DRAWINGS

The present invention encompasses various embodiments. For purposes of better elucidating the basic principle of the invention, one of these embodiments is shown in the drawing and will be described in greater detail below. The following is shown in a schematic diagram:

FIG. 1—a perspective view of a carrier material during the production of printed circuit structures by means of electromagnetic radiation;

FIG. 2—an enlarged view of a section, cut along line II-II, of the carrier material shown in FIG. 1;

FIG. 3—a perspective view of the carrier material shown in FIG. 1, in a metallization bath; and

FIG. 4—the sectional view of the carrier material shown in FIG. 2, with a copper layer.

### DETAILED DESCRIPTION OF A PREFERRED EMBODIMENT

The method according to the present invention as well as the production of printed circuit structures 1 that can be realized in this manner are presented in greater detail on the basis of FIGS. 1 to 3. Here, a plate-shaped carrier material 2 is first exposed to selective electromagnetic radiation 3 of an Nd:YAG laser in order to create the printed circuit structures 1 on the carrier material 2 as highly reactive aluminum particles by breaking-up non-conductive aluminum nitride that is extremely finely dispersed in the carrier material 2. At the same time, nitrogen is released, which prevents an undesired oxidation of the aluminum particles.

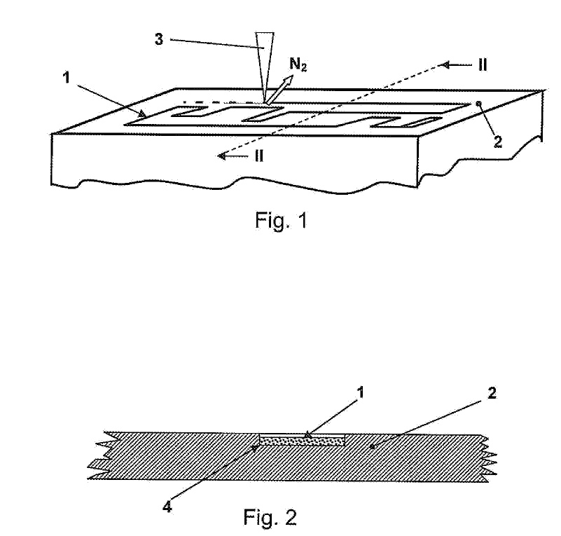

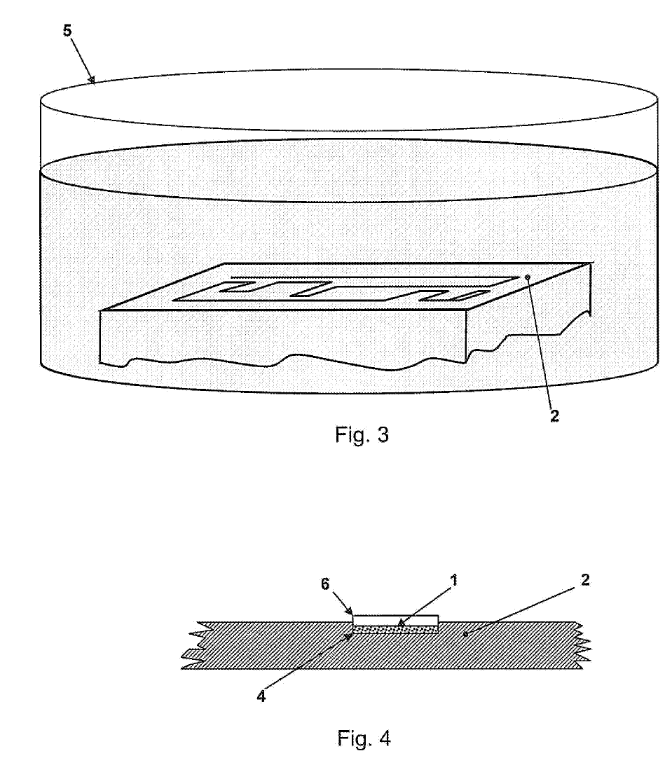

As the sectional view in FIG. 2 shows, the breaking-up of the non-conductive aluminum nitride contained in the carrier material 2 in the form of a conductive layer consisting of aluminum particles concurrently leads to an ablation of the layer of carrier material 2 that is close to the surface, so that the aluminum particles are formed in a groove-shaped recess 4. This recess 4 facilitates not only the creation of the structure surface of the aluminum particles thus formed, which promotes bonding, but also the current-free layer formation in a metallization bath 5, as shown in FIG. 3.

Following a treatment in an ultrasound cleaning bath, the carrier material 2 is suspended 5, for instance, by means of a frame (not shown here), in the metallization bath that is configured as a commercially available chemically reductive copper-plating bath. This is where the copper layers 6 shown in FIG. 6 are built up current-free onto the printed circuit structures 1 in the irradiated areas.

What is claimed is:

1. A method for producing a printed circuit structure on a modified high-molecular carrier material containing non-conductive aluminum nitride in finely dispersed form, the method comprising:
breaking up the non-conductive aluminum nitride in the carrier material so as to create the printed circuit structure on a high-molecular surface of the carrier material as electrically conductive surface phases with highly reactive aluminum particles;
releasing the aluminum particles in a high concentration with concurrent formation of nitrogen and with the ablation of the high-molecular carrier material, wherein areas surrounding the printed circuit structure remain unchanged.

2. The method as recited in claim 1, wherein the creating of the printed circuit structure of the carrier material is carried out in a current-free metallization bath.

3. The method as recited in claim 1, further comprising applying at least one of chromium, copper, nickel and gold during the metallization.

4. The method as recited in claim 1, wherein the breaking up is performed using electromagnetic radiation of a laser.

5. The method as recited in claim 4, wherein the electromagnetic radiation is within a wavelength spectrum from 0.125 μm to 11.0 μm.

6. The method as recited in claim 1, further comprising releasing highly reactive aluminum particles in an area of the printed circuit structure to be created along with nitrogen formation and removal of the high-molecular material, using electromagnetic radiation, and wherein the aluminum particles are metallized by chemical reduction.

7. The method as recited in claim 1, wherein the high-molecular material includes a polymer.

8. The method as recited in claim 1, further comprising incorporating an insoluble aluminum-nitride powder into the high-molecular surface of the carrier material, and subsequently processing the carrier material into components or applying the carrier material as a coating onto components.

9. The method as recited in claim 8, wherein the insoluble aluminum-nitride powder is highly stable under heat and resistant in aqueous, acidic or alkaline metallization baths.

10. The method as recited in claim 1, wherein the breaking up of the aluminum nitride causes the aluminum particles to be formed with a concurrent ablation of the high-molecular material, along with a splitting off of nitrogen so as to create a structure surface that promotes bonding.

11. The method as recited in claim 8, wherein the aluminum nitride powder includes a mixture of aluminum nitride with 1.0% to 5.0% yttrium oxide so as to further improve a bonding strength of the metal layer.

12. The method as recited in claim 1, wherein the non-conductive carrier material includes one of a plastic and a polymer ceramic.

13. A printed circuit structure device comprising:
a carrier material including a modified high-molecular surface and containing a non-conductive aluminum nitride in finely dispersed form; and
a printed circuit structure disposed on high-molecular surface as highly reactive aluminum particles from breaking up of the non-conductive aluminum nitride in the carrier material, wherein areas surrounding the printed circuit structure remain unchanged.

14. The printed circuit structure as recited in claim 13, wherein, in addition to the non-conductive aluminum nitride, the carrier material also contains higher oxides having a structure of at least one of spinels and organic, thermally stable metal chelate complexes.

15. The printed circuit structure as recited in claim 13, wherein the non-conductive carrier material includes at least one of a plastic and a polymer ceramic.
